(19) United States
(12) Patent Application Publication
(10) Pub. No.: US 2006/0270127 A1
(43) Pub. Date: Nov. 30, 2006

(54) Method of forming dual gate variable VT device

(75) Inventors: Yu-Chih Lai, Jhubei City (TW); Tz-Yang Wu, Hsinchu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/136,952

(22) Filed: May 24, 2005

(51) Int. Cl. H01L 21/84; H01L 29/80

(52) U.S. Cl. 438/157; 257/274

(57) ABSTRACT

A dual gate device having independently adjusted voltage thresholds with improved performance and reliability and method for forming the same, the method including providing a semiconductor substrate comprising a first gate structure on a first gate dielectric layer overlying a high voltage threshold (HVT) portion of the semiconductor substrate; then forming first sidewall spacers adjacent either side of the first gate structure; then forming a low voltage threshold (LVT) portion of the semiconductor substrate; then forming a second gate dielectric layer on the LVT portion; and, then forming a second gate structure on the second gate dielectric layer.

### FIELD OF THE INVENTION

This invention generally relates to formation of CMOS devices by integrated circuit manufacturing processes and more particularly to formation of dual gate MOSFETs with improved performance, reliability, and yield.

### BACKGROUND OF THE INVENTION

As is well-known, increased device density, together with higher speed performance and lower power consumption are major driving forces in improving integrated circuit manufacturing devices and methods. For example, a challenge for CMOS design considerations is to simultaneously meet both low power and high-speed requirements. For example, if V_{DD} is reduced to lower power consumption and voltage threshold V_{T} is fixed, I_{drive} is reduced which has the undesirable trade-off of reducing performance speed of a device. On the other hand, if V_{T} is lowered to increase I_{drive}, then the undesirable trade-off of increasing I_{OFF} (standby current) will occur. Individual FET gates are associated with a delay time period for signal propagation in semiconductor device circuitry. The delay time period, in turn, is inversely proportional to the drive current (I_{drive}). Therefore, increasing the drive current will increase the performance speed or Figure of Merit (FOM) of a CMOS device.

One approach to overcoming the offsetting trade-offs in CMOS design between I_{drive} and I_{OFF} is the use of dual transistors with different voltage thresholds (V_{T}), also referred to as dual V_{T}, or dual gate technology. For example two transistors are used, one referred to as a high V_{T} (HVT) transistor and the other referred to as a low V_{T} (LVT) transistor. The LVT transistors are used in speed-critical portions of circuitry to increase I_{drive} thereby increasing device speed performance, whereas the HVT transistors are used in non-speed-critical portions of the circuitry. By using the LVT transistors only in speed-critical portions of the circuitry, the overall I_{OFF}, or standby current in only marginally increased.

One problem in the prior art relates to the difficulty of parallel manufacturing of the HVT transistor and the LVT transistor. For example the respective HVT and LVT transistors can have topography differences in the manufacturing process thereby make manufacturing processes increasingly difficult as device sizes are scaled down and process windows, including dry etching process windows, become narrower.

There is therefore a need in the integrated circuit manufacturing art including manufacturing of dual V_{T} transistors to improve manufacturing methods to thereby improve device performance and reliability.

It is therefore an object of the present invention to provide improved dual V_{T} transistor manufacturing methods to thereby improve device performance and reliability, while overcoming other shortcomings of the prior art.

### SUMMARY OF THE INVENTION

To achieve the foregoing and other objects, and in accordance with the purposes of the present invention, as embodied and broadly described herein, the present invention provides a dual gate device having independently adjusted voltage thresholds with improved performance and reliability and method for forming the same.

In a first embodiment, the method includes providing a semiconductor substrate comprising a first gate structure on a first gate dielectric layer overlying a high voltage threshold (HVT) portion of the semiconductor substrate; then forming first sidewall spacers adjacent either side of the first gate structure; then forming a low voltage threshold (LVT) portion of the semiconductor substrate; then forming a second gate dielectric layer on the LVT portion; and, then forming a second gate structure on the second gate dielectric layer.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1G are cross sectional schematic views of exemplary portions of a CMOS device including dual V_{T} transistors at stages of manufacture according to an embodiment of the present invention.

FIG. 2 is a process flow diagram including several embodiments of the present invention.

### DETAILED DESCRIPTION OF THE PREFERRED EMBODIMENTS

Although the method of the present invention is explained with reference to an exemplary dual VT transistors, also referred to as split dual gate devices, it will be appreciated that the method of the present invention is generally applicable to the parallel manufacture of CMOS devices having different topographies and having independently adjusted voltage thresholds (V_{T}) whereby a dry etching process to form respective gate structures having different respective electrical operating characteristics may be improved.

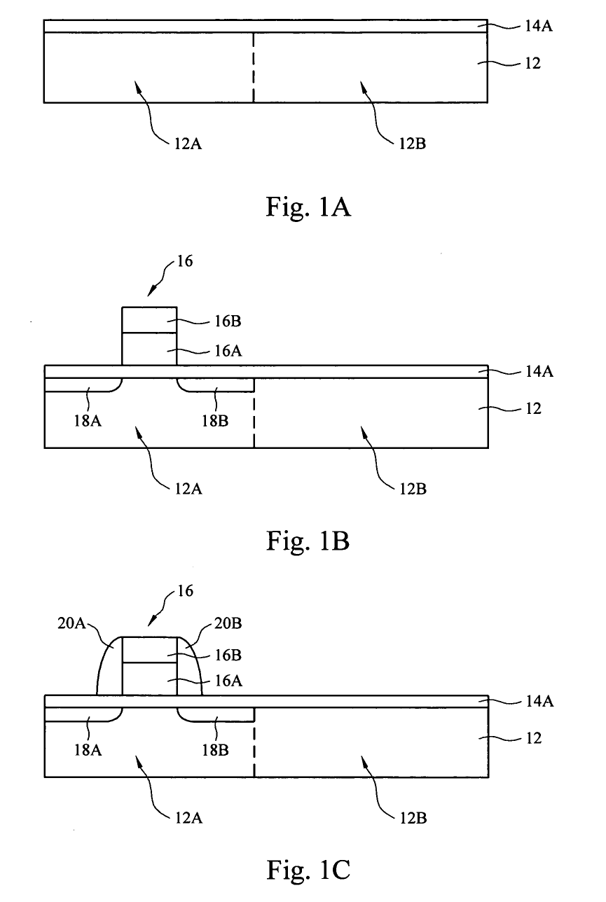

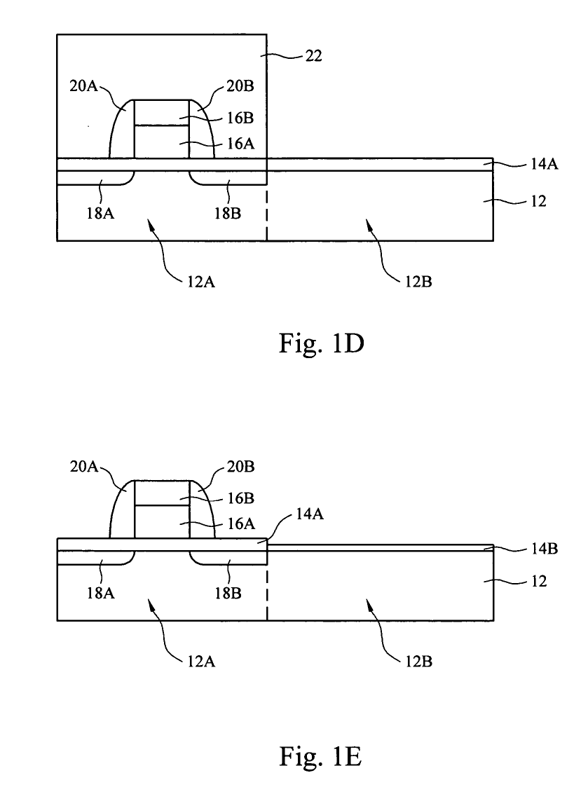

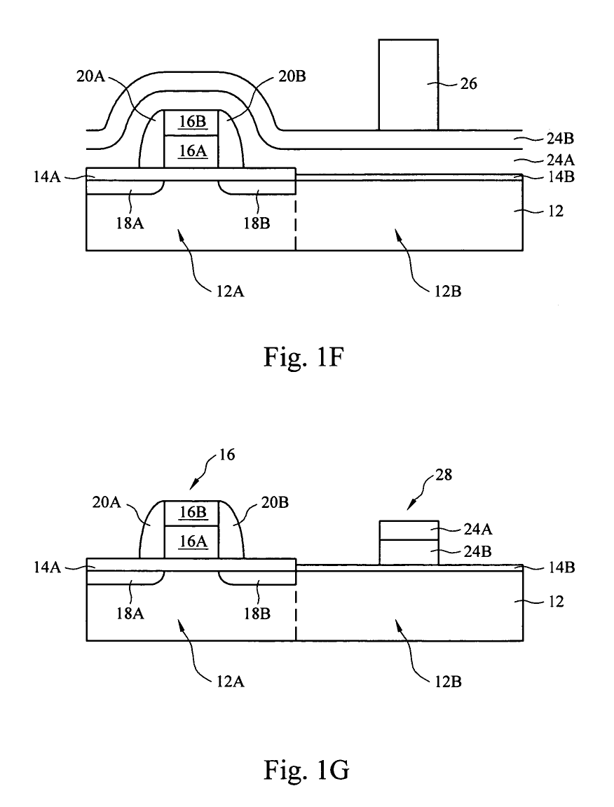

Referring to FIGS. 1A-1G in an exemplary process flow for forming the dual V_{T} MOSFETS of the present invention, are shown cross-sectional schematic views of a portion of a semiconductor wafer at stages in an exemplary integrated circuit manufacturing process.

For example, referring to FIG. 1A, is shown a semiconductor substrate 12, which may include silicon, strained semiconductor, compound semiconductor, multi-layered semiconductors, or combinations thereof. For example, the substrate 12 may include, but is not limited to, silicon, silicon on insulator (SOI), stacked SOI (SSOI), stacked SiGe on insulator (S—SiGeOI), SiGeOI, and GeOI, or combinations thereof. In a preferred embodiment, the substrate is silicon including doped well regions 12A and 12B making up respective high V_{T} transistor (HVT) and low V_{T} transistor (LVT) substrate regions. It will be appreciated that a shallow trench isolation (STI) (not shown) may optionally be formed to divide doped well regions 12A and 12B.

Still referring to FIG. 1A, the HTV portion of the substrate is doped by conventional ion implant methods to adjust a voltage threshold (V_{T}) level for the HTV portion of the substrate 12A. For example a sacrificial oxide layer (not shown) is first grown (e.g., from about 150 Angstroms to about 250 Angstroms) over the substrate 12 by conventional thermal growth methods, followed by photolithographic patterning processes to expose portions of the HTV portion e.g., 12A of the substrate followed by one or more ion implant processes. The sacrificial oxide is then stripped by a wet dip in dilute HF (e.g., (H₂O:HF at 50:1) and a gate dielectric layer 14A, for example silicon dioxide is thermally grown at a temperature of from about 900° C. to about 1050° C. to a thickness of about 150 Angstroms to about 250 Angstroms) over the substrate 12, including portions 12A and 12B.

Referring to FIG. 1B, a gate electrode 16 is then formed over the HTV portion 12A of the substrate by conventional CVD deposition, photolithographic patterning and dry etching processes. For example, polysilicon and optionally polycide uppermost layers are formed followed by photolithographically patterning the layers for dry etching a gate electrode 16 to stop on the gate dielectric layer 14A. For example the HTV gate electrode 16 may be formed entirely of doped or undoped polysilicon or may be formed having a bottom portion e.g., 16A formed of polysilicon and an upper portion e.g., 16B formed of polycide, preferably tungsten silicide (e.g., WSiₓ). It will be appreciated that other metal silicides (polycides) may be used in forming the upper portion 16B of HTV gate electrode 16, e.g., TiSi₂, CoSi₂, NiSi, PtSi, and the like. The polycide is formed by conventional methods including, for example, first depositing a metal layer over the polysilicon layer followed by an annealing process to from a low electrical resistance phase of the metal silicide (polycide). Following formation of the HTV gate electrode 16, conventional photolithographic patterning processes e.g., covering LTV portion 12B and exposing HTV portion 12A, followed by ion implantation and annealing is carried out to form LDD doped HTV regions in the substrate portion 12A e.g., 18A and 18B adjacent the HTV gate electrode 16.

Referring to FIG. 1C, in an important aspect of the invention, sidewall spacers are formed adjacent the gate electrode 16 prior to forming a gate electrode over the LTV portion of the substrate 12B. For example, a silicon oxide layer, preferably TEOS oxide is first deposited by a conventional CVD process over the process surface, followed by an isotropic etch process using either a conventional TEOS oxide dry etch chemistry, e.g., fluorocarbons and/or perfluorocarbons and/or a wet etch process e.g., using dilute HF. More preferably an isotropic dry etch process is carried out for at least the final stages of the isotropic etch process to stop on the gate oxide layer 14A forming TEOS oxide spacers e.g., 20A and 20B adjacent the gate electrode 16. Advantageously, isotropic dry etching the TEOS oxide can be preformed with good selectivity with respect to the thermally grown oxide layer 14A without damaging the gate oxide layer 14A. It will be appreciated that the spacer 20A and 20B may be formed of other material having a good etching selectivity with respect to the gate dielectric may be used including e.g., silicon nitride or silicon oxynitride, including forming composite spacers such as oxide-nitride-oxide (ONO) spacers.

Referring to FIG. 1D, an LTV voltage threshold (V_{T}) implant process is then carried out after first photolithographically patterning the process surface to cover the HTV substrate portion 12A with e.g., photoresist portion 22 and exposing the LTV substrate portion 12B. For example the LTV substrate portion 12B is doped to adjust a V_{T} to operate at relatively lower voltages compared to the V_{T} of the HTV portion 12A (e.g., positive or negative voltages). It will be appreciated that the TEOS oxide spacers 20A and 20B may be formed either prior to or following the LTV voltage threshold (V_{T}) implant process, but that forming the spacers prior to the LTV voltage threshold (V_{T}) implant process as shown, is preferred and advantageously reduces the number of process steps required.

Referring to FIG. 1E, following the LTV voltage threshold (V_{T}) implant process, the LTV portion of gate dielectric, e.g. thermally grown oxide 14A is subjected to a conventional buffered oxide etch, for example a wet dip in buffered dilute HF, to remove the gate oxide portion 14A overlying the LTV region. Following removal of the photoresist portion 22 and a conventional substrate cleaning process, a conventional thermal oxide growth process is then carried out at about 900° C. to about 1050° C. to grow second gate oxide layer 14B over the process surface including the LTV portion of the substrate 12B, preferably having a thickness of from about 50 Angstroms to about 150 Angstroms, preferably thinner compared to gate oxide portion 14A.

Referring to FIG. 1F, a doped or undoped polysilicon layer e.g., 24A is then deposited over the process surface including HTV and LTV substrate portions 12A and 12B. Optionally an uppermost polycide (metal silicide) portion e.g., 24B is formed, using the same or a different metal silicide as gate electrode portion 16B, preferably tungsten silicide (e.g., WSiₓ). A photolithographic patterning process is then carried out to pattern a second gate electrode photoresist portion with e.g., 26 for forming a second gate electrode.

Referring to FIG. 1G, a conventional polysilicon or polycide/polysilicon dry etching process is then carried out to form LTV gate electrode 28 to stop on the gate oxide layer 14B. Conventional processes are then carried out, to complete the formation of HTV and LTV transistors e.g., including sidewall spacer formation 30A and 30B as well as forming independently adjustable doped regions e.g., LDD (formed before spacers) and drain (S/D) regions (formed after spacers) e.g., together shown as 32A and 32B. It will be appreciated that the foregoing method may be used to form individual HTV and LTV gate structures including intervening electrical isolation structures (shallow trench isolation) which is not shown),or HTV and LTV gate structures in a split dual gate configuration.

It will be appreciated that advantageously, the spacers 20A and 20B may be left in place, such that spacers e.g., 30A and 30B formed adjacent LTV gate structure 28 may be formed having a different width to thereby alter the placement of LDD and main S/D regions e.g., 32A and 32B, of the respective HTV and LTV transistors. As a result, additional electrical operating characteristics of the LTV and HTV transistors may be independently adjusted.

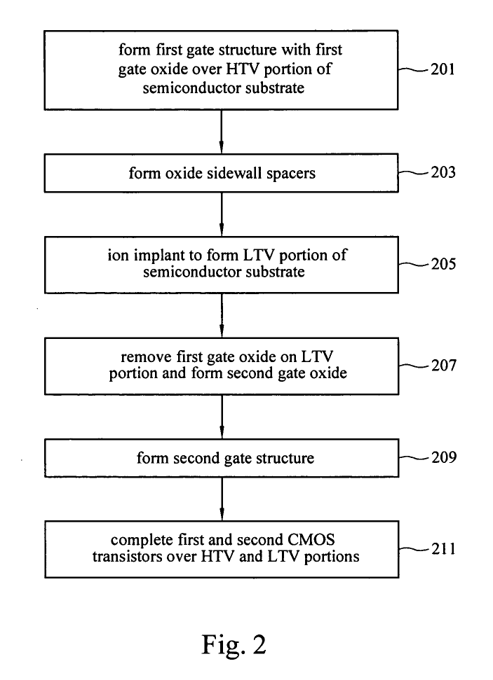

Referring to FIG. 2 is a process flow diagram including several embodiments of the present invention. In process 201, a first gate structure including a first gate oxide is formed over a high V_{T} (HTV) portion of a semiconductor substrate. In process 203, oxide sidewall spacers are formed adjacent the first gate structure. In process 205, a low V_{T} portion (LTV) portion of the semiconductor substrate is formed (ion implanted) adjacent the HTV portion. In process 207, the first gate oxide over the LTV portion is removed and a second gate oxide thinner than the first gate oxide is formed. In process 209, a second gate structure is formed over low V_{T} portion of the semiconductor substrate. In process 211, high V_{T} and low V_{T} CMOS transistors are completed respectively over the HTV and LTV substrate portions.

Thus, according to the present invention, a method has been presented for forming HTV and LTV gate structures in a parallel process whereby sidewall spacers are formed adjacent the HTV gate structure prior to forming the LTV gate structure. Advantageously, according to the present invention, problems according to prior art processes have been overcome including shortcomings related to polysilicon and/or polycide/polysilicon dry etching to form the HTV and LTV gate structures. For example, it has been found that in prior art processes, without LTV gate sidewall spacers, that the difference in topography of the polysilicon or polycide/polysilicon layer prior to LTV gate formation increased the formation of polysilicon etching residue adjacent the HVT gate structure and/or contributed to undesired overetching (e.g., microtrenching) into the source and drain regions adjacent the HTV gate structure.

According to the present invention, the addition of sidewall spacers prior to formation of the LTV gate structures, advantageously acts to prevent the problems of polysilicon residue formation or undesirable overetching adjacent the HTV gate structure during LTV gate structure formation. Advantageously, the method of the present invention allows the voltage threshold (V_{T}) of the HTV and LTV transistors to be independently adjusted while preserving HVT gate oxide and source and drain region quality. Thus, device performance, reliability, and yield are improved significantly over prior art processes.

The preferred embodiments, aspects, and features of the invention having been described, it will be apparent to those skilled in the art that numerous variations, modifications, and substitutions may be made without departing from the spirit of the invention as disclosed and further claimed below.

1. A method of forming a dual gate device comprising the steps of:
providing a semiconductor substrate comprising a first gate structure on a first gate dielectric layer overlying a high Voltage threshold (HVT) portion of the semiconductor substrate;
forming sidewall spacers adjacent either side of the first gate structure;
forming a low Voltage threshold (LVT) portion of the semiconductor substrate;
forming a second gate dielectric layer on the LVT portion; and,
forming a second gate structure on the LVT portion.

2. The method of claim 1, wherein the first and second gate structures comprise a respective first and second gate electrode comprising a material selected from the group consisting of polysilicon and a metal silicide.

3. The method of claim 2, wherein the metal silicide is selected from the group consisting of tungsten silicide, titanium silicide, cobalt silicide, nickel silicide, and platinum silicide.

4. The method of claim 2, wherein the metal silicide consists essentially of tungsten silicide.

5. The method of claim 1, wherein the first and second gate dielectric layer comprise silicon dioxide.

6. The method of claim 1, wherein the first gate dielectric layer is formed to be thicker than the second gate dielectric layer.

7. The method of claim 1, wherein the sidewall spacers are formed of TEOS silicon oxide.

8. The method of claim 7, wherein the step of forming the sidewall spacers comprises an isotropic etch process selected from the group consisting of a dry and a wet etch process.

9. The method of claim 8, wherein the dry etch process stops on the first gate dielectric layer.

10. The method of claim 1, wherein LDD doped regions are formed according to ion implantation in the HTV portion adjacent the first gate structure prior to the step of forming the sidewall spacers.

11. The method of claim 1, wherein the step of forming the second gate structure comprises the steps of:
forming a material layer over the HTV and LTV portions selected from the group consisting of polysilicon and metal silicide;
photolithographically patterning a resist to cover an HVT portion of the semiconductor substrate; and, dry etching the material layer to stop on the second gate dielectric layer.

12. The method of claim 1, wherein the first gate dielectric layer is removed over the LTV portion prior to forming the second gate dielectric layer.

13. The method of claim 1, wherein the HTV portions and LTV portions are formed according to ion implantation to operate at respectively higher and lower device operating Voltages.

14. A method of forming a dual gate device having Independently adjusted Voltage thresholds with improved performance and reliability comprising the steps of:
providing a semiconductor substrate;
forming a high Voltage threshold (HVT) substrate portion according to a first ion implantation process;
forming a first gate oxide on the HVT substrate portion;
forming a first gate electrode on the first gate oxide;
forming oxide sidewall spacers adjacent either side of the first gate electrode;
forming a low Voltage threshold (LVT) substrate portion according to a second ion implantation process;
removing the first gate oxide over the LVT portion;
forming a second gate oxide on the LVT substrate portion; and,
forming a second gate electrode on the second gate oxide.

15. The method of claim 14, wherein the first and second gate electrodes comprise a material selected from the group consisting of polysilicon and a metal silicide.

16. The method of claim 15, wherein the metal silicide is selected from the group consisting of tungsten silicide, titanium silicide, cobalt silicide, nickel silicide, and platinum silicide.

17. The method of claim 15, wherein the metal silicide consists essentially of tungsten silicide.

18. The method of claim 14, wherein the first and second gate oxide layers comprise thermally grown silicon dioxide.

19. The method of claim 14, wherein the first gate oxide layer is formed to be thicker than the second gate oxide layer.

20. The method of claim 14, wherein the oxide sidewall spacers are formed of TEOS silicon oxide.

21. The method of claim 20, wherein the step of forming the oxide sidewall spacers comprises an isotropic oxide etch process selected from the group consisting of a dry and a wet oxide etch process.

22. The method of claim 21, wherein the dry oxide etch process stops on the first gate oxide layer.

23. The method of claim 14, wherein LDD doped regions are formed according to ion implantation in the HTV portion adjacent the first gate structure prior to the step of forming the oxide sidewall spacers.

24. The method of claim 14, wherein the step of forming the second gate structure comprises the steps of:
forming a material layer over the HTV and LTV portions selected from the group consisting of polysilicon and metal silicide;
photolithographically patterning a resist to cover an HVT portion of the semiconductor substrate; and,
dry etching the material layer to stop on the second gate dielectric layer.

25. The method of claim 14, wherein the HTV portions and LTV portions are formed to operate at respectively higher and lower device operating Voltages.
